(19) United States
(12) Patent Application Publication
(10) Pub. No.: US 2007/0096961 A1
(43) Pub. Date: May 3, 2007

(54) Signal processing device

(76) Inventors: Shiro Sakiyama, Kyoto (JP); Masayoshi Kinoshita, Osaka (JP); Shiro Dosho, Osaka (JP)

Correspondence Address: MCDERMOTT WILL & EMERY LLP, 600 13TH STREET, NW, WASHINGTON, DC, 20005-3096, US

(21) Appl. No.: 10/580,842

(22) PCT Filed: Oct. 14, 2004
(86) PCT No.: PCT/JP04/15577

§ 371 Date: May 26, 2006

(30) Foreign Application Priority Data
Nov. 26, 2003 (JP) 2003-395624

(51) Int. Cl. H03M 7/30

(52) U.S. Cl. 341/76

(57) ABSTRACT

In a signal processing device which performs data compression, a thinning circuit 1 generates thinned data by thinning input PCM data. For example, when a sampling rate fs of the PCM data (original data) is fs=10 Hz, thinned data of fs=1 Hz is generated. The determination circuit 2 controls the selection circuit 4 so that, based on the following expression:
TOTAL1=|X(n)−X(n−1)|+|X(n−1)−X(n−2)|+ . . . +|X(n−8)−X(n−9)|
if TOTAL1>C1, the input PCM data is selected, and if otherwise the thinned data is selected. The selected data and the determination result information of the determination circuit 2 are written into a memory 3. Therefore, data compression is performed with respect to original data with a simple circuit configuration and without losing required information of the original data.

### TECHNICAL FIELD

The present invention relates to a configuration of a signal processing device which compresses data which has been converted into a digital signal in predetermined sampling intervals, and stores the data into a memory.

### BACKGROUND ART

Generally, when data which has been converted into a digital signal in predetermined sampling intervals is recorded, compression of the data before recording into a memory with a higher data compression ratio contributes to a lower-cost system.

As a method for compressing PCM audio data, compression techniques called DPCM (Differential Pulse Code Modulation) and ADPCM (Adaptive Differential Pulse Code Modulation) have been widely used. The former is a technique of performing data compression by recording differential data between each piece of data. The latter is a technique of performing data compression by recording differential data with respect to predicted data, and it is said that by generating predicted data considerably close to original digital data, the data can be compressed by a factor of about ⅓. In addition, regarding image data, data compression may be performed by converting time-series data into frequency domain data, and thereafter, cutting off a high-frequency component, thereof data compression may be performed using differential data between portions having a high correlation of frames, and the like.

For example, JP No. 5-300019 A discloses a method for compressing digital data to be recorded into a memory by controlling the sampling rate of an input analog signal. According to the publication, a plurality of AD converters for converting an input analog signal into a digital signal are provided, which are operated at sampling rates different from each other, and output PCM data having different sampling rates. The input analog signal is also input to an analog band-pass filter, in which a high frequency component is emphasized. By determining the emphasized signal level, a piece of digital data is selected from PCM data output from the plurality of AD converters. In an embodiment described in the publication, the AD converters have sampling frequencies of 18.9 KHz and 37.8 KHz, so that data can be compressed by a maximum factor of about ½.

When the ADPCM data compression is used, data can be compressed by a factor of about ⅓. However, this data compression disadvantageously requires a large-scale digital circuit (DSP, etc.) which requires a program. Also, disadvantageously, a higher order of predicted data needs to be calculated so as to increase a compression ratio, resulting in a more enormous computation amount.

The method of performing data compression by converting time-series data into frequency domain data and cutting off a high frequency component, is inappropriate with respect to a data sequence which has an important meaning in the high frequency component. Also, this method disadvantageously requires a large-scale digital circuit and an enormous computation amount as in ADPCM.

In addition, if the technique described in the publication is applied to audio data, the amount of consumed memory can be reduced by a factor of about ½, but a plurality of AD converters, and analog parts (an analog band-pass filter, etc.) are required to configure a data compression system. Therefore, when a system in which a memory amount is effectively reduced is configured, a number of analog parts are inevitably required, advantageously resulting in a significant increase in cost.

### DISCLOSURE OF THE INVENTION

An object of the present invention is to provide a signal processing device which performs data compression while holding a high data compression effect and without losing an information component from a data sequence which has an important meaning in a high frequency component, which is cut off by the conventional technique, and has a simple circuit configuration without requiring a number of circuits.

To achieve the object, in the present invention, one or more thinning circuits which thin input digital data (original data) into thinned data having a large sampling interval, and it is determined which of the thinned data and the original data is selected in accordance with a predetermined criterion, in predetermined intervals, and the selected data (the original data or the thinned data) is written into a memory.

Specifically, the present invention provides a signal processing device for receiving data which has been converted into a digital signal in predetermined sampling intervals, compressing the input original data, and recording the resultant data into a memory. The device comprises thinning means for thinning the original data into thinned data having a sampling interval different from the predetermined sampling interval, determining means for analyzing the original data in predetermined constant intervals, and based on a predetermined criterion, determining which of the original data and the thinned data of the thinning means is selected, data writing means for writing selected data which is one of the original data and the thinned data of the thinning means, into the memory in the predetermined constant intervals, based on a determination result of the determining means; and information writing means for writing determination result information of the determining means into the memory.

In the signal processing device of the present invention, the thinning means includes a plurality of thinning means for thinning the original data into a plurality of pieces of thinned data having a plurality of sampling intervals different from the predetermined sampling interval, and the predetermined constant interval is equal to a largest sampling interval of the plurality of different sampling intervals.

Further, in the signal processing device of the present invention, the plurality of sampling intervals have a relationship of an integral multiple with respect to the sampling interval of the original data, and the plurality of sampling intervals have a relationship of an integral multiple with respect to each other.

In addition, in the signal processing device of the present invention, the thinning means calculates an average value of the original data within one sampling interval, and the average value data is representative data which is used as thinned data.

Also, in the signal processing device of the present invention, the thinning means calculates a data value which is located at substantially a center when original data is sorted within one sampling interval, and the center value data is representative data which is used as thinned data.

Further, in the signal processing device of the present invention, the predetermined criterion of the determining means is determined by comparing a result of calculation of a feature amount of each piece of data within each predetermined sampling interval of original data, with a predetermined threshold value.

In addition, in the signal processing device of the present invention, the feature amount is a sum value of absolute differential values between each adjacent piece of data within each predetermined sampling interval of original data.

Also, in the signal processing device of the present invention, the feature amount is a maximum value of absolute differential values between each adjacent piece of data within each predetermined sampling interval of original data.

Further, in the signal processing device of the present invention, the feature amount is a sum value or a maximum value of second-order derivatives between each adjacent piece of data within each predetermined sampling interval of original data.

In addition, in the signal processing device of the present invention, the feature amount is any combination of two or more of a sum value and a maximum value of absolute differential values between each adjacent piece of data within each predetermined sampling interval of original data, and a sum value or a maximum value of second-order derivatives between the each adjacent piece of data.

Also, in the signal processing device of the present invention, the predetermined threshold value is changed, depending on the feature amount of original data.

Further, in the signal processing device of the present invention, the information writing means writes determination result information at the same address as an address of data written into a memory by the data writing means, the determination result information being appended to the data.

In addition, in the signal processing device of the present invention, the information writing means writes a plurality of pieces of determination result information together at an address different from an address of data written into a memory by the data writing means.

Also, the present invention provides a signal processing device for receiving data which has been converted into a digital signal in predetermined sampling intervals, compressing the input original data, and recording the resultant data into a memory. The device comprises determining means for analyzing the original data in predetermined constant intervals, and based on a predetermined criterion, determining whether or not the original data is selected, thinning means for thinning the original data into thinned data having a sampling interval larger than the predetermined sampling interval, when the original data is not selected, based on a determination result of the determining means, data writing means for writing selected data which is one of the original data and the thinned data of the thinning means, into the memory in the predetermined constant intervals, based on the determination result of the determining means, and information writing means for writing determination result information of the determining means into the memory.

Accordingly, in the present invention, for example, when original data has a sampling frequency of 10 Hz and thinned data has a sampling frequency of 1 Hz, the amount of data to be written into a memory can be compressed to a maximum of 1/10 of the amount of the original data. In addition, if the predetermined criterion of the determining means is changed as appropriate, data compression can be performed with respect to a data sequence having an important meaning in a high frequency component without losing the high frequency information component. Further, data compression can be performed with a simple configuration without requiring a large-scale digital circuit (DSP, etc.) which requires a program, a plurality of AD converters, or the like, no matter that the thinning means and the determining means are provided.

Particularly, in the present invention, the data analysis for selecting one of original data and a plurality of pieces of thinned data having different sampling intervals, is performed in largest sampling intervals of the thinned data, resulting in a simple configuration of the determination circuit.

Also, in the present invention, the sampling intervals of a plurality of pieces of thinned data have a relationship of an integral multiple with respect to the sampling interval of original data, so that timing of data selection and memory writing can be performed in constant intervals, resulting in an easy control.

Further, in the present invention, average value data of pieces of data within each sampling interval of original data is thinned data, whereby aliasing noise from a high frequency to a low frequency can be reduced to a large extent as compared to simple thinning.

In addition, in the present invention, center data of pieces of data within each sampling interval of original data is thinned data, thereby making it possible to cut off a single noise component.

Also, in the present invention, a predetermined criterion for selecting original data or thinned data is determined by comparing a feature amount of the original data with a predetermined threshold value, whereby data compression can be performed without losing a required feature amount from the original data. Particularly, since a sum value of absolute differential values between each adjacent piece of data is a feature amount of the original data, compression can be performed without losing a high frequency component of the original data. Further, since a maximum value of absolute differential values between each adjacent piece of data is a feature amount of the original data, compression can be performed without losing a single pulse-like component of the original data. In addition, since a sum value or a maximum value of second-order derivatives between each adjacent piece of data is a feature amount, compression can be performed without losing an inflection component of the original data. Also, since any combination of the above-described feature amounts is a feature amount, compression can be performed without losing all the various feature amounts of the original data.

Further, in the present invention, since the predetermined threshold value used as the criterion can be changed, depending on a feature amount of original data, the signal processing device can be utilized to satisfactorily perform data compression with respect to various original data, resulting in high general versatility as a signal processing device.

Therefore, according to the signal processing device of the present invention, it is possible to provide a data compression device which has a simple circuit configuration while holding a high data compression effect and without losing a required information component from original data.

### BRIEF DESCRIPTION OF THE DRAWINGS

FIG. 1 is a diagram illustrating a configuration of a signal processing device according to a first embodiment of the present invention.

FIG. 2 is a diagram illustrating a waveform of original data in the first embodiment.

FIG. 3(a) is a diagram illustrating a waveform of data written into a memory when, in the first embodiment, a sum value of absolute differential values of pieces of data is determined as a feature amount of original data and a threshold value=12. FIG. 3(b) is a diagram illustrating a waveform of data written into a memory when the threshold value=26. FIG. 3(c) is a diagram illustrating a waveform of data written into a memory when the threshold value=74.

FIG. 4 is a diagram illustrating a waveform of thinned data which is obtained by thinning the original data of FIG. 2 to 1/10.

FIG. 5(a) is a diagram illustrating a waveform of compressed data when a maximum value of absolute differential values of pieces of data is determined as a feature amount of original data and a threshold value=4. FIG. 5(b) is a diagram illustrating a waveform of compressed data when the threshold value=7. FIG. 5(c) is a diagram illustrating a waveform of compressed data when the threshold value=22.

FIG. 6(a) is a diagram illustrating a first example of a method of storing compressed data into a memory. FIG. 6(b) is a diagram illustrating a second example of the storing method.

FIG. 7 is a diagram illustrating a graph in which compressed data is decompressed.

FIG. 8 is a diagram illustrating a configuration of a signal processing device according to a second embodiment of the present invention.

### BEST MODE FOR CARRYING OUT THE INVENTION

Hereinafter, a signal processing device according to an embodiment of the present invention will be described with reference to the accompanying drawings.

### First Embodiment

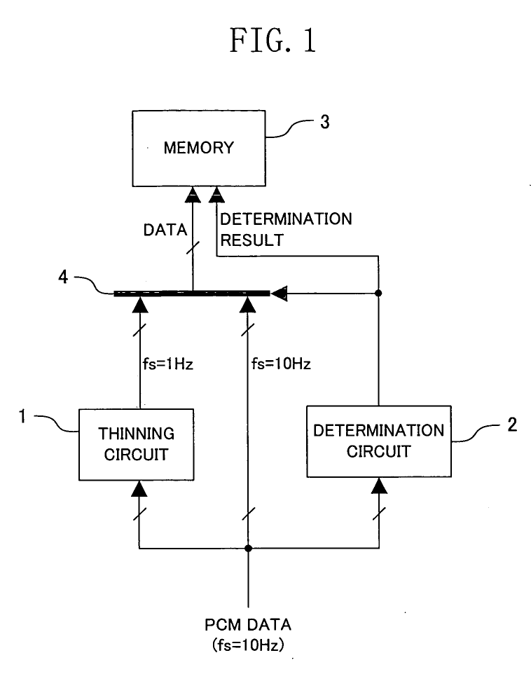

FIG. 1 is a diagram illustrating a configuration of a first embodiment according to the present invention.

In FIG. 1, 1 indicates a thinning circuit, 2 indicates a determination circuit, 3 indicates a memory, and 4 indicates a selection circuit.

As illustrated in FIG. 1, PCM data (original data) obtained by converting an analog signal into a digital signal with a sampling frequency of 10 Hz, is input to the thinning circuit 1 and the determination circuit 2.

For example, the thinning circuit (thinning means) 1 thins the input PCM data having a sampling frequency of 10 Hz into thinned data having a sampling frequency of 1 Hz. A most commonly used technique for thinning input data is a process called moving average filtering, and calculation is generally performed based on expression 1.
X(n)+X(n−1)+X(n−2)+ . . . +X(n−9)/10 (expression 1)

In expression 1, X(n), X(n−1), . . . indicate a data sequence of the input PCM data having a sampling frequency of 10 Hz, and X(n−1) means data which is transferred and input immediately before X(n). The calculation of expression 1 corresponds to a process which calculates an average of 10 consecutive adjacent pieces of data. In the thinning circuit 1, the calculation of expression 1 is performed in units of 10 pieces of input data, and the result of the calculation is output as a representative value, so that the data amount of output thinned data is compressed into one-tenth of the data amount of the input data.

In the determination circuit (determining means) 2, 10 pieces of input data is grouped into one set, and for each set, one of the thinned data of the thinning circuit 1 and the input PCM data (original data) is selected and written into the memory 3.

An example of this criterion is described by expression 2 below.
TOTAL1=|X(n)−X(n−1)|+|X(n−1)−X(n−2)|+ . . . +|X(n−8)−X(n−9)| (expression 2)
if TOTAL1>C1 select input PCM data
else select thinned PCM data

In expression 2, C1 indicates a threshold constant, and |X(n)−X(n−1)| indicates the absolute value of the difference between data X(n) and data X(n−1). In expression 2, for 10 consecutive pieces of data from data X(n) to data X(n−9), the absolute value of the difference between each adjacent piece of data is calculated, and it is determined whether the calculation result TOTAL1 is larger or smaller than the predetermined threshold value C1. When the calculation result TOTAL1 is larger than the threshold value C1, the input PCM data (a 10-piece data sequence X(n) to X(n−9)) are selected, and when otherwise, the thinned data from the thinning circuit 2 (thinned input PCM data) is selected.

The selection circuit (data writing means) 4 selects data based on the determination result of the determination circuit 2, and writes the selected data into the memory 3.

In this embodiment, the input PCM data is divided in units of one second interval (predetermined constant interval) (into groups of 10 pieces of sampled data), and the determination circuit 2 performs analysis (expression 2) in units of 10 pieces of data thus divided. Therefore, when all the determination results of the determination circuit 2 are smaller than or equal to the predetermined threshold value C1, only the thinned data of the thinning circuit 1 is written into the memory 3, so that the data amount is reduced to 10% at maximum in this embodiment.

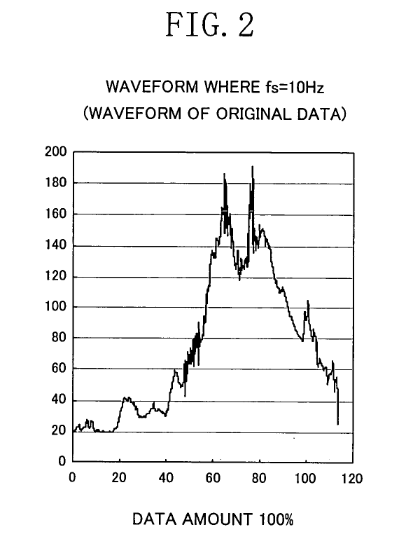

Exemplary analysis indicating an effect of this embodiment when the predetermined criterion of expression 2 is applied, is illustrated in FIGS. 2 to 4.

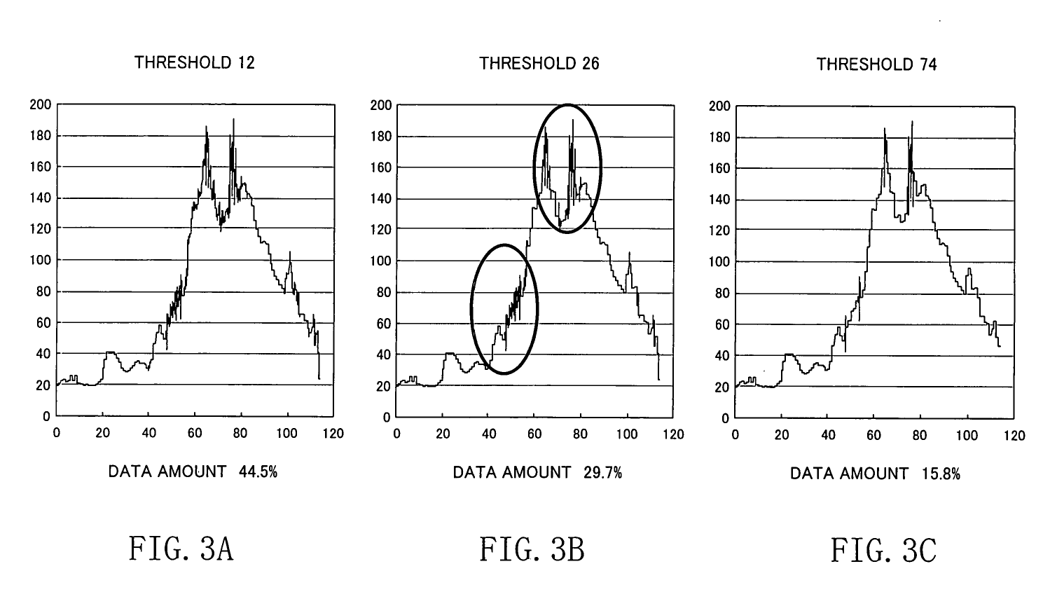

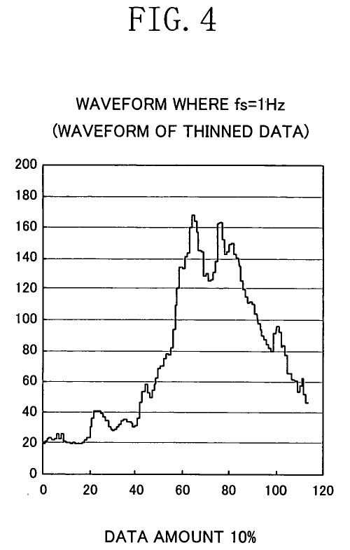

FIG. 2 illustrates a waveform of original data which is input PCM data having a sampling frequency of 10 Hz, and is used to demonstrate the effect of this embodiment. FIG. 4 illustrates a waveform of thinned data which is obtained by subjecting the original data of FIG. 2 to the moving average filtering process of expression 1 to thin the sampled data to 1/10. Therefore, in the graph of FIG. 4, the data amount is 10% of the original data. FIGS. 3(a) to 3(c) are graphs illustrating the effect of this embodiment. FIG. 3(a) illustrates that, when the threshold value C1 of expression 2 is set to be “12”, the data amount can be reduced to 44.5% of the original data. Similarly, FIGS. 3(b) and 3(c) illustrate that, when the threshold value C1 is set to be “26” and “74”, the data amount can be reduced to 29.7% and 15.8% of the input PCM data, respectively.

The threshold value C1 for the determination is selected so that a feature amount required with respect to input data can be sufficiently extracted. For example, when the original data of FIG. 2 is a data sequence about a test for people in a hospital, a peak value of the data, and a differential value indicating a sudden change in the data are considered to be particularly important feature amounts. In the graph of FIG. 3(b) where the threshold value C1 is set to be “26”, as can be seen from regions enclosed with ellipses, peak values and sudden data changes in the waveform of the original data can be reproduced with high fidelity with respect to the original data. As illustrated in FIG. 3(b), even when data compression is performed to 29.7%, a sufficient amount of required information is contained.

In data compression, data thinning compression in which an input frequency band is limited to a low level is often used. In this case, however, as can be seen from FIG. 4, high frequency components of data, such as a peak value, a sudden data change, and the like, are lost. However, in this embodiment, required high frequency components of input data are secured as they are in the original input data, so that reproduction can be achieved without reducing the information amount of the required high frequency components. This embodiment is particularly effective as means for compressing data which is obtained by continuous measurement so as to detect an abnormality in each part of the body. This is because an abnormality often causes a sudden change, so that it is important to analyze a portion in which data suddenly changes.

If the threshold value C1 can be changed, depending on the feature amount of input data, the data compression device can be utilized to compress various input data sequences, resulting in an improvement in the general versatility of the data compression device.

(Another Example of Predetermined Criterion)

A criterion for the determination circuit 2 employing expression 3 is also effective.
TOTAL2=MAX[|X(n)−X(n−1)|, |X(n−1)−X(n−2)|, . . . , |X(n−8)−X(n−9)|] (expression 3)

if TOTAL2>C2 select input PCM data

else select thinned PCM data

In expression 3, MAX[|X(n)−X(n−1)|, |X(n−1)−X(n−2)|, . . . , |X(n−8)−X(n−9)|] means that, for a data sequence of 10 consecutive pieces of data X(n) to X(n−9), the maximum value of absolute differential values between adjacent pieces of data is calculated. It is determined whether the calculation result TOTAL2 is larger or smaller than a predetermined threshold value C2. When the calculation result TOTAL2 is larger than the threshold value C2, the input PCM data (the data sequence of X(n) to X(n−9)) is selected, and when otherwise, the thinned data (thinned PCM data) from the thinning circuit 2 is selected. The selection circuit 4 selects data based on the determination result, and writes the selected data into the memory 3.

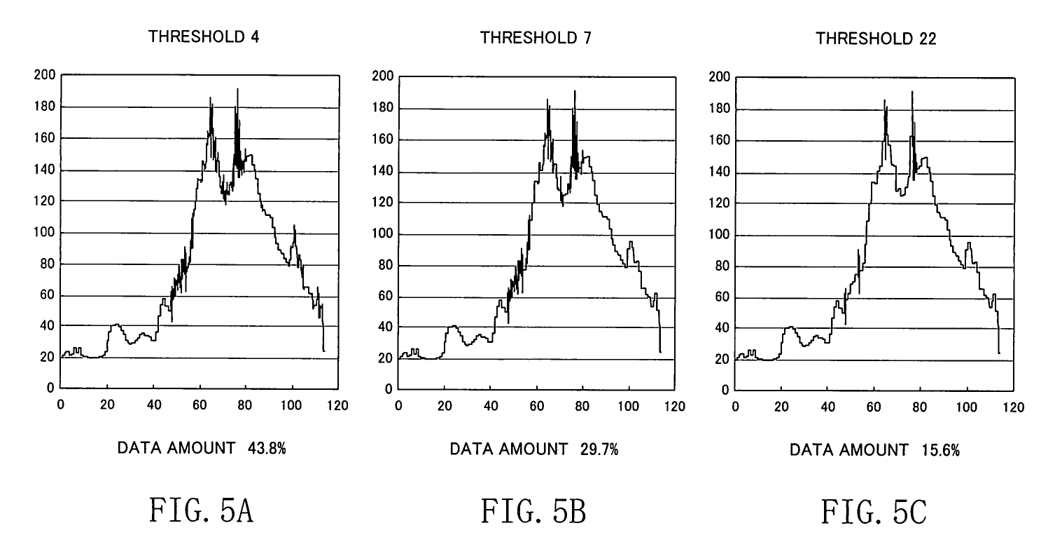

Exemplary analysis indicating an effect of this embodiment when the criterion of expression 3 is applied, is illustrated in FIGS. 5(a) to 5(c).

Input data is PCM data having a sampling frequency of 10 Hz and has the waveform of the original data of FIG. 2. As described above, FIG. 4 illustrates the waveform of thinned data which is obtained by subjecting the original data of FIG. 2 to the moving average filtering process of expression 1 to thin the sampled data to 1/10. FIGS. 5(a) to 5(c) are graphs illustrating an effect when the criterion of expression 3 is used. FIG. 5(a) illustrates that, when the threshold value C2 of expression 3 is set to be “4”, the data amount can be reduced to 43.8% of the original data. Similarly, FIGS. 5(b) and 5(c) illustrate that, when the threshold value C2 is set to be “7” and “22”, the data amount can be reduced to 29.7% and 15.6% of the original data, respectively.

The graphs of FIGS. 3 and 5 are compared. There is not a large difference therebetween, but while the criterion of expression 2 is used to determine high-frequency powers for 10 pieces of data, the criterion of expression 3 is used to determine only one high-frequency power. Therefore, when the criterion of expression 3 is used, noise-like information is likely to be included. When the noise-like information is not really noise, but is required feature amount data, the criterion of expression 3 is considered to be one of the effective criteria.

As described above, it is desirable to provide a criterion optimal to a required feature amount, depending on input original data. For example, if a second-order derivative of original data is an important feature amount, the sum value of second-order derivative amounts or the maximum value of the second-order derivative amounts is desirably used as the criterion. Further, if the plurality of feature amounts described above are important for input original data, the logical addition (OR) of the respective determination results may be used as a final determination result.

(Another Example of Thinning Circuit)

Although the first-order moving average filter of expression 1 has been used as the thinning circuit 1 in this embodiment, a median filter indicated by expression 4 below is also effective.
Medium[X(n), X(n−1), X(n−2), . . . , X(n−9)] (expression 4)

In expression 4, X(n), X(n−1), . . . indicate a data sequence of input PCM data having a sampling frequency of 10 Hz as in expression 1. X(n−1) means data which is transferred and input immediately before X(n). The calculation of expression 4 means a calculation in which 10 consecutive pieces of data is sorted, and center value data located at substantially a center thereof is output as a representative value. The output data amount is compressed to 1/10 as in expression 1. The median filter of expression 4 has an advantage that output data is not affected by a noise component included in the data sequence, as compared to the moving average filter of expression 1, but has a disadvantage that data phase information is lost or a computation amount is more or less large as compared to the calculation of expression 1. Thus, the thinning filter can be achieved by various methods. In addition to the above-described thinning circuits employing a moving average filter and a median filter, a second or more-order moving average filter or a higher-order low-pass filter can be used to thin input data.

(Method for Storing Compressed Data)

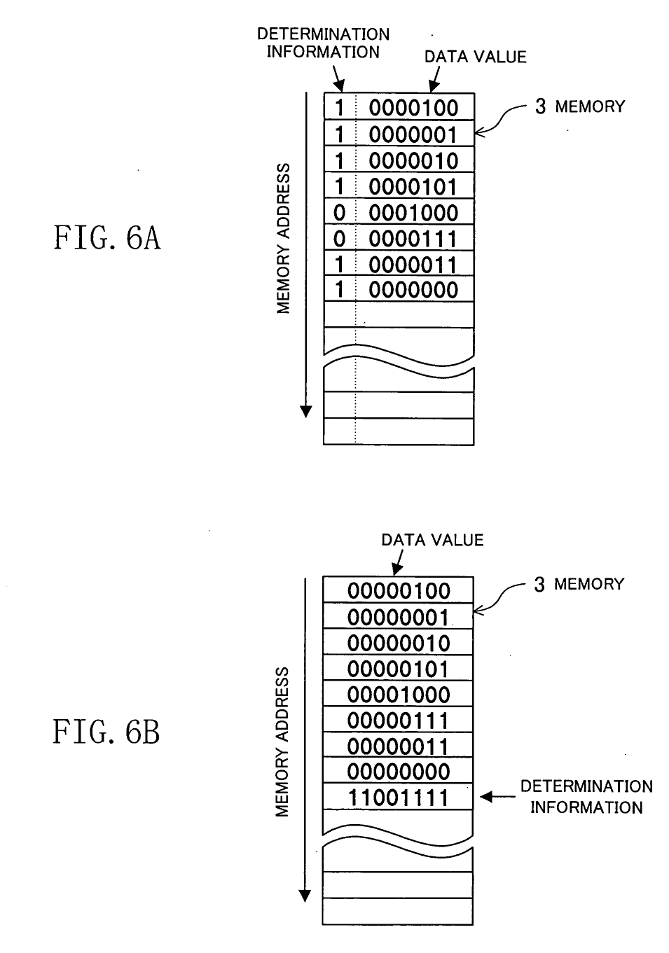

Next, a method for storing compressed data into the memory 3 will be described with reference to FIG. 6. FIG. 6 illustrates an example where data selected by the selection circuit 4 of FIG. 1 is written into the memory 3 having a data word length of 8 bits.

FIG. 6(a) illustrates an example where the word length of input data is 7 bits, and for 7-bit data selected by the selection circuit 4, information about the determination result of the determination circuit 2 is appended as 1-bit data at the same address, so that a total of 8-bit data is successively written into a memory address space of the memory 3. Here, when input data having a sampling frequency of 10 Hz is selected, the determination result information is represented by “1”, and when thinned data having a sampling frequency of 1 Hz is selected, the determination result information is represented by “0”, thereby identifying the determination result information.

FIG. 6(b) illustrates an example where the word length of input data is 8 bits, and 8-bit data selected by the selection circuit 4 is successively written into an address space of the memory 3. Every time 8-word compressed data is written, 8 pieces of 1-bit data which is the determination result information of the determination circuit 2 are collected and are written together as 8-bit information to another address. In this example, each determination result corresponding to 8-word data corresponds to 8-bit data sequentially from the right. In this example, determination result information is written in units of 8-word data. Alternatively, determination result information can be written in units of 16 words or 32 words as long as data and determination result information can be easily associated with each other, and the memory capacity can be efficiently utilized.

As described above, when compressed data is stored into the memory 3, there are a method for storing a determination result into the same address as that of data as illustrated in FIG. 6(a), and a method for storing for storing a determination result into another address as illustrated in FIG. 6(b). It is desirable to adopt a most optimal storing method, depending on the relationship between the data word length of the memory 3 and the word length of input data. In addition, the following means may be considered: the word length of a memory is regarded as 1 bit, a word of data is sequentially written, and thereafter, determination result information is written; and after several words of data is sequentially written, determination result information corresponding to the several words is written.

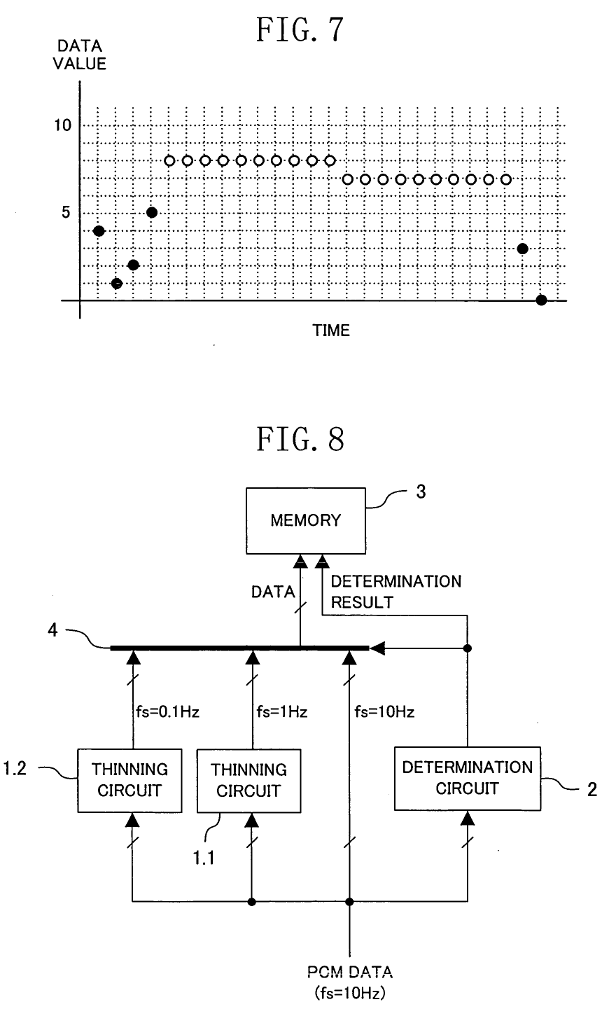

When compressed data stored in the memory 3 is plotted onto a graph, the data can be easily decompressed based on the determination result information. In the example of FIG. 6, when a determination information result corresponding to data is “1”, 10 pieces of data stored in the memory 3 may be plotted in sampling intervals of 0.1 seconds, and when a determination information result corresponding to data is “0”, 10 pieces of the same data may be plotted during one second. An exemplary graph on which the compressed data of FIG. 6 stored in the memory 3 are plotted is illustrated in FIG. 7. In FIG. 7, original data is represented by closed circles, and thinned data is represented by open circles (note that there are actually 10 consecutive pieces of original data, but only several pieces of them are drawn in FIG. 7). In FIG. 7, the horizontal axis represents time corresponding to a sampling interval of input data, and the vertical axis represents the data value. Thus, compressed data can be easily decompressed based on determination result information for each piece of data (in other words, information having a sampling frequency) stored in the memory 3.

### Second Embodiment

Next, a second embodiment of the present invention will be described.

Although there is one kind of sampling interval in which thinned data is output by the thinning circuit 1 in the first embodiment, a plurality of thinning circuits having different thinning rates can be provided. This embodiment illustrates such an example.

FIG. 8 illustrates the second embodiment of the present invention. In FIG. 8, the same parts as those of FIG. 1 are referenced with the same reference numerals. In FIG. 8, 1.1 and 1.2 indicate thinning circuits, 2 indicates a determination circuit, 3 indicates a memory, and 4 indicates a selection circuit.

As illustrated in FIG. 8, PCM data obtained by converting an analog signal into a digital signal with a sampling frequency of 10 Hz, is input to the two thinning circuits 1.1 and 1.2 and the determination circuit 2.

The thinning circuit 1.1 thins the input PCM data having a sampling frequency of 10 Hz into data having a sampling frequency of 1 Hz, as in the thinning circuit 1 of FIG. 1.

The thinning circuit 1.2 thins the input PCM data having a sampling frequency of 10 Hz into data having a sampling frequency of 0.1 Hz. In this case, determination is performed in the determination circuit 2 in accordance with expression 5.
TOTAL1=|X(n)−X(n−1)|+|X(n−1)−X(n−2)|+ . . . +|X(n−98)−X(n−99)| (expression 5)

if TOTAL1>C3 select input PCM data

else if TOTAL1>C4 select thinned PCM data of fs=1 Hz

else select thinned PCM data of fs=0.1 Hz

In expression 5, C3 and C4 (C3>C4) are threshold constants, and |X(n)−X(n−1)| represents the absolute differential value between data X(n) and data X(n−1). In expression 5, for 100 consecutive pieces of data X(n) to X(n−99), the sum of absolute differential values between adjacent pieces of data, as in expression 2. When the calculation result TOTAL1 is larger than the first threshold value C3, 100 pieces of input PCM data (original data) are selected. On the other hand, when the calculation result TOTAL1 is larger than the second threshold value C4 and is smaller than or equal to the first threshold value C3, 10 pieces of PCM data (thinned data, fs=1 Hz) are selected. When the calculation result TOTAL1 is smaller than or equal to the second threshold value C4, one piece of PCM data (thinned data, fs=0.1 Hz) is selected. The selection circuit 4 selects data based on the determination result, and writes the selected data into the memory 3.

As described above, when the thinning circuit 1.2 having a sampling frequency of 0.1 Hz is further prepared, it is possible to reduce the data amount of the input PCM data to a maximum of about 1/100. In this embodiment, a considerably high effect is obtained for a data group having characteristics in which a period of time during which there are significant data changes is considerably short with respect to all data. Although determination result information stored in the memory 3 is identified using 1-bit data in the first embodiment, two bits are required in this embodiment.

As described above, by preparing the thinning circuits 1.1 and 1.2 having different thinning rates and determining which thinned data is selected among a plurality of pieces of thinned data using the determination circuit 2 in addition to selection between original data and thinned data, a data compression device having a higher data reduction effect is obtained.

Assuming that the thinning circuits 1.1 and 1.2 having a plurality of sampling intervals are provided as illustrated in FIG. 8, if the determination in the determination circuit 2 is performed by analysis with respect to input data in largest sampling intervals of the plurality of sampling intervals of the plurality of thinning circuits, and thinning intervals (sampling intervals) of the plurality of thinning circuits have a relationship of an integral multiple with respect to input PCM data, and these thinning intervals are integral multiples therebetween, the switching timing of the selection circuit 4 can be invariably performed in predetermined intervals, whereby the control of a hardware configuration can be more easily performed.

Although it has been described above that the thinning circuit is configured to invariably perform a process of thinning input PCM data, the thinning circuit may be configured to perform the thinning process only when it is determined that the determination circuit 2 does not select input PCM data (original data).

### INDUSTRIAL APPLICABILITY

As described above, the signal processing device of the present invention can have a simple circuit configuration while holding a high data compression effect and without losing a required information component from original data, and therefore, is useful as a data compression device and the like.

1-6. (canceled)

7. A signal processing device for receiving data which has been converted into a digital signal in predetermined sampling intervals, compressing the input original data, and recording the resultant data into a memory, the device comprising:
thinning means for thinning the original data into thinned data having a sampling interval different from the predetermined sampling interval;
determining means for analyzing the original data in predetermined constant intervals, and based on a predetermined criterion, determining which of the original data and the thinned data of the thinning means is selected;
data writing means for writing selected data which is one of the original data and the thinned data of the thinning means, into the memory in the predetermined constant intervals, based on a determination result of the determining means;
information writing means for writing determination result information of the determining means into the memory;
wherein the predetermined criterion of the determining means is determined by comparing a result of calculation of a feature amount of each piece of data within each predetermined sampling interval of original data, with a predetermined threshold value; and
wherein the feature amount is a sum value of absolute differential values between each adjacent piece of data within each predetermined sampling interval of original data.

8. A signal processing device for receiving data which has been converted into a digital signal in predetermined sampling intervals, compressing the input original data, and recording the resultant data into a memory, the device comprising:
thinning means for thinning the original data into thinned data having a sampling interval different from the predetermined sampling interval;
determining means for analyzing the original data in predetermined constant intervals, and based on a predetermined criterion, determining which of the original data and the thinned data of the thinning means is selected;
data writing means for writing selected data which is one of the original data and the thinned data of the thinning means, into the memory in the predetermined constant intervals, based on a determination result of the determining means;
information writing means for writing determination result information of the determining means into the memory;
wherein the predetermined criterion of the determining means is determined by comparing a result of calculation of a feature amount of each piece of data within each predetermined sampling interval of original data, with a predetermined threshold value; and
wherein the feature amount is a maximum value of absolute differential values between each adjacent piece of data within each predetermined sampling interval of original data.

9. A signal processing device for receiving data which has been converted into a digital signal in predetermined sampling intervals, compressing the input original data, and recording the resultant data into a memory, the device comprising:
thinning means for thinning the original data into thinned data having a sampling interval different from the predetermined sampling interval;
determining means for analyzing the original data in predetermined constant intervals, and based on a predetermined criterion, determining which of the original data and the thinned data of the thinning means is selected;
data writing means for writing selected data which is one of the original data and the thinned data of the thinning means, into the memory in the predetermined constant intervals, based on a determination result of the determining means;
information writing means for writing determination result information of the determining means into the memory;
wherein the predetermined criterion of the determining means is determined by comparing a result of calculation of a feature amount of each piece of data within each predetermined sampling interval of original data, with a predetermined threshold value; and
wherein the feature amount is a sum value or a maximum value of second-order derivatives between each adjacent piece of data within each predetermined sampling interval of original data.

10. A signal processing device for receiving data which has been converted into a digital signal in predetermined sampling intervals, compressing the input original data, and recording the resultant data into a memory, the device comprising:
thinning means for thinning the original data into thinned data having a sampling interval different from the predetermined sampling interval;
determining means for analyzing the original data in predetermined constant intervals, and based on a predetermined criterion, determining which of the original data and the thinned data of the thinning means is selected;
data writing means for writing selected data which is one of the original data and the thinned data of the thinning means, into the memory in the predetermined constant intervals, based on a determination result of the determining means;
information writing means for writing determination result information of the determining means into the memory;
wherein the predetermined criterion of the determining means is determined by comparing a result of calculation of a feature amount of each piece of data within each predetermined sampling interval of original data, with a predetermined threshold value; and
wherein the feature amount is any combination of two or more of a sum value and a maximum value of absolute differential values between each adjacent piece of data within each predetermined sampling interval of original data, and a sum value or a maximum value of second-order derivatives between the each adjacent piece of data.

11. A signal processing device for receiving data which has been converted into a digital signal in predetermined sampling intervals, compressing the input original data, and recording the resultant data into a memory, the device comprising:
thinning means for thinning the original data into thinned data having a sampling interval different from the predetermined sampling interval;
determining means for analyzing the original data in predetermined constant intervals, and based on a predetermined criterion, determining which of the original data and the thinned data of the thinning means is selected;
data writing means for writing selected data which is one of the original data and the thinned data of the thinning means, into the memory in the predetermined constant intervals, based on a determination result of the determining means;
information writing means for writing determination result information of the determining means into the memory;
wherein the predetermined criterion of the determining means is determined by comparing a result of calculation of a feature amount of each piece of data within each predetermined sampling interval of original data, with a predetermined threshold value; and
wherein the predetermined threshold value is changed, depending on the feature amount of original data.

12-14. (canceled)
